(19) United States
(12) Patent Application Publication
(10) Pub. No.: US 2013/0082850 A1
(43) Pub. Date: Apr. 4, 2013

(54) DATA ENCODING APPARATUS, DATA DECODING APPARATUS AND METHODS THEREOF

(71) Applicant: Hidenori TAKESHIMA, Kanagawa-ken (JP)

(72) Inventor: Hidenori TAKESHIMA, Kanagawa-ken (JP)

(21) Appl. No.: 13/629,182

(22) Filed: Sep. 27, 2012

(30) Foreign Application Priority Data
Sep. 30, 2011 (JP) 2011-218672

(51) Int. Cl. H03M 7/40; H03M 7/00

(52) U.S. Cl. 341/65; 341/50

(57) ABSTRACT

a In a data encoding apparatus, an acquisition unit acquires an input data including a plurality of arranged data. A conversion unit searches a data group including a first consecutive data and a second data adjacent to the first consecutive data, each data of the first consecutive data having a first value and the second data having a second value, and converts the data group into an intermediate data. A selection unit selects a selected encoding method among a plurality of encoding methods, at a time of encoding the intermediate data based on where a beginning of the data group corresponding to the intermediate data exists in the input data. An encoding unit can encode the intermediate data by using the selected encoding method.

### CROSS-REFERENCE TO RELATED APPLICATION

This application is based upon and claims the benefit of priority from Japanese Patent Application No. 2011-218672, filed on Sep. 30, 2011; the entire contents of which are incorporated herein by reference.

### FIELD

Embodiments described herein relate generally to an apparatus and a method for encoding and decoding data.

### BACKGROUND

Image encoding methods (e.g. progressive JPEG) can acquire transformation coefficients by applying Discrete Cosine Transform (DCT) and quantization to an 8×8 block in an image, and encode the transformation coefficients by scanning several times.

An existing data encoding method can encode the transformation coefficients of each scanning unit, the scanning unit being a range of the transformation coefficients to be encoded at each time of scanning, in advance. When encoding the transformation coefficients in each scanning unit, such an existing data encoding method encodes each symbol in a group of consecutive zeros and non-zero which is regarded as an intermediate data.

In this method, however, when both symbols in front of and behind a separation point of the scanning units are zero, the transformation coefficients are separated at the separation point. Consequently, two intermediate data are generated.

Therefore, the background data encoding method cannot encode data efficiently because each of the intermediate data is encoded separately. It is expected such a method will not generate two intermediate data in the above case.

### BRIEF DESCRIPTION OF THE DRAWINGS

FIG. 1 is a block diagram of a data encoding apparatus according to a first embodiment.

FIG. 2 is a flow chart of processing of the data encoding apparatus.

FIGS. 3(a), 3(b), 3(c), and 3(d) are explanation diagrams of processing of the data encoding apparatus.

FIG. 4 is an explanation diagram of zigzag scanning.

FIG. 5 is a flow chart of processing of the data encoding apparatus according to a modification of the first embodiment.

FIG. 6 is a bock diagram of a data decoding apparatus according to a second embodiment.

FIG. 7 is a flow chart of processing of the data decoding apparatus.

### DETAILED DESCRIPTION

According to one embodiment, an apparatus for encoding data includes an acquisition unit, a conversion unit, a selection unit, and an encoding unit. The acquisition unit is configured to acquire an input data of a plurality of arranged data. The conversion unit is configured to search a data group including a first consecutive data and a second data adjacent to the first consecutive data, each data of the first consecutive data having a first value and the second data having a second value, and to convert the data group into an intermediate data. The selection unit is configured to select a selected encoding method among a plurality of encoding methods, at a time of encoding the intermediate data based on where the beginning of the data group corresponding to the intermediate data exists in the input data. The encoding unit is configured to encode the intermediate data by using the selected encoding method.

According to another embodiment, an apparatus for decoding data includes an acquisition unit, a setting unit, a selection unit, a decoding unit, and a conversion unit. The acquisition unit is configured to acquire an encoded data. The setting unit is configured to set a remark position representing a position of data to be decoded. The selection unit is configured to select a selected decoding method among a plurality of decoding methods, based on where the beginning of the data at the remark position exists in the encoded data. The decoding unit is configured to decode the encoded data to an intermediate data by using the selected decoding method. The conversion unit is configured to convert the intermediate data including a first consecutive data and a second data adjacent to the first consecutive data, each data of the first consecutive data having a first value and the second data having a second value.

Various embodiments will be described hereinafter with reference to the accompanying drawings.

### The First Embodiment

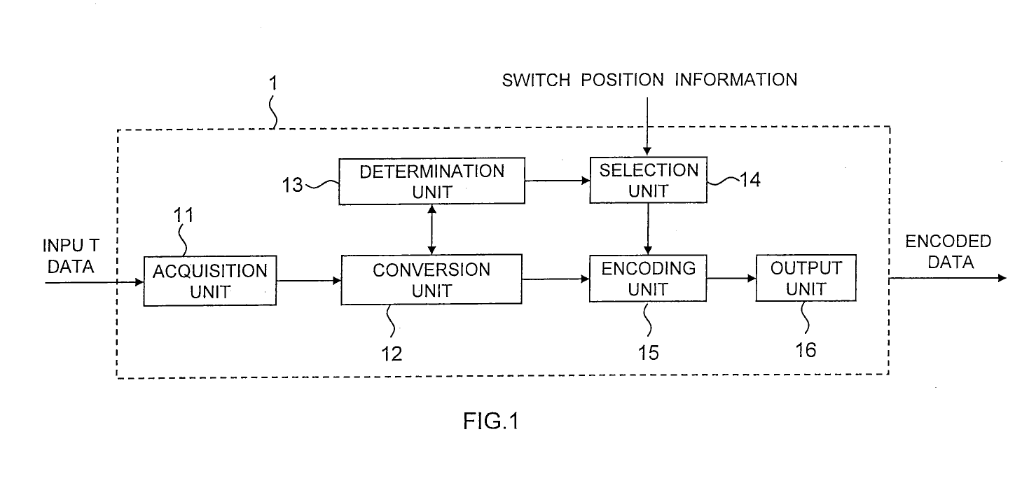

As shown in FIG. 1, a data encoding apparatus 1 according to a first embodiment is suitable for an ultrasonic diagnostic equipment and an image transmission equipment in a thin client system. The data encoding apparatus 1 obtains encoded data by encoding an acquired image.

The data encoding apparatus 1 converts each data group to corresponding intermediate data. The data group is a group of data of consecutive numerical values (discrete values) . The intermediate data is data that can be converted to the corresponding original consecutive numerical values. The amount of the intermediate data is preferably less than the amount of the original numerical values. The data encoding apparatus 1 obtains encoded data by applying an entropy coder to each of the intermediate data.

In this embodiment, the data encoding apparatus 1 converts each data group including zero-run length and non-zero adjacent to the zero-run length to the corresponding intermediate data. The data encoding apparatus 1 selects an entropy coder based on where the beginning of the data group corresponding to the intermediate data exists in the input data. The data encoding apparatus 1 encodes the intermediate data by using a selected entropy coding method.

FIG. 1 is a block diagram of the data encoding apparatus 1. The data encoding apparatus 1 includes an acquisition unit 11, a conversion unit 12, a determination unit 13, a selection unit 14, an encoding unit 15, and an output unit 16.

The acquisition unit 11 acquires an input image data.

The conversion unit 12 searches the data group including zero-run length and non-zero adjacent to the zero-run length by scanning the acquired input data, and converts each of the data group to the corresponding intermediate data.

The determination unit 13 determines a position of the beginning of the data group corresponding to the intermediate data in the input data. Hereinafter, the position is referred to as the remark position.

The selection unit 14 selects an entropy coder for each of the intermediate data based on the determined remark position. The selection unit 14 utilizes switch position information for selecting the entropy coder. For example, the switch position information can be input from a user.

The encoding unit 15 encodes each of the intermediate data by using the selected entropy coder, to generate the encoded data.

The output unit 16 outputs the obtained encoded data.

The acquisition unit 11, the conversion unit 12, the determination unit 13, the selection unit 14, the encoding unit 15, and the output unit 16 may be realized by a central processing unit (CPU) or a processor and a memory used thereby.

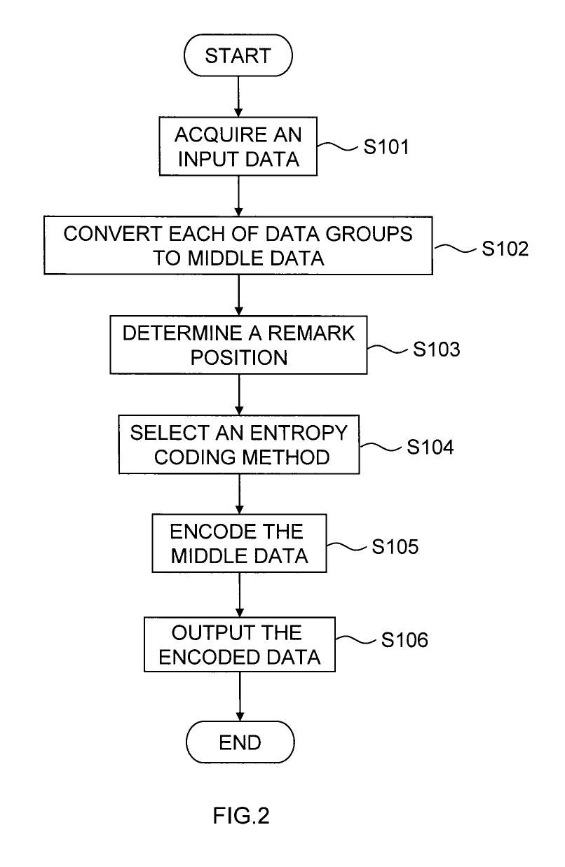

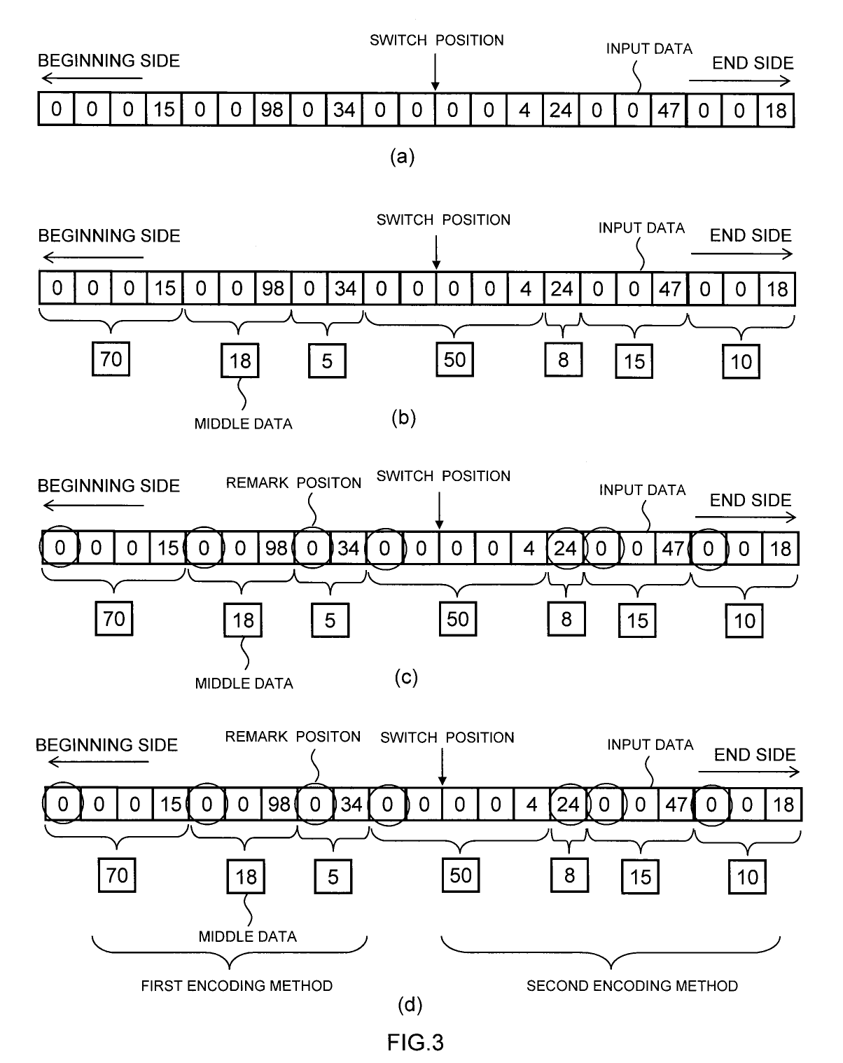

FIG. 2 is a flow chart of processing performed by the data encoding apparatus 1. FIGS. 3(a)-3(d) are explanation diagrams of processing by the data encoding apparatus 1.

The acquisition unit 11 acquires an input data (step S101). For example, the acquisition unit 11 can acquire an array of numbers of 8 bits, 16 bits, or 24 bits that are sample values of an image data as the input data. FIG. 3(a) shows the input data acquired by the acquisition unit 11. The input data is data including a plurality of numbers. The left side is the beginning of the data in FIG. 3 (a). The information of a switch position (the switch position information) has been acquired and is held by the selection unit 14.

The conversion unit 12 searches the data group by scanning the acquired input data, and converts each of the data group to corresponding intermediate data (step S102). FIG. 3(b) shows the intermediate data converted from the input data by the conversion unit 12. For example, the conversion unit 12 stores a conversion table assigning identification numbers to a group of the number of consecutive zeros (zero-run length) and a non-zero adjacent to the preceding zeros, and converts each of the data group to the corresponding intermediate data by using the conversion table. The correspondence of the data group and the intermediate data in the data table is set in advance. The intermediate data in FIG. 3(b) is an example.

The determination unit 13, as to each of the intermediate data, determines the remark position in the corresponding data group. In FIG. 3(c), the position of the data in the input data is the remark position. Each encircled zero is the remark position. For example, the determination unit 13 can determine what number the data of the remark position is from the beginning of the input data.

The selection unit 14 selects an entropy coder for each of the intermediate data based on the determined remark position and the switch position information (step S104). As shown in FIG. 3(d), for example, the selection unit 14 selects a first entropy coder when the remark position is further towards the beginning of the data group. The selection unit 14 selects a second entropy coder when the remark position is further towards the end of the data group.

The encoding unit 15 encodes each of the intermediate data by using the selected entropy coder, to generate the encoded data (step S105). In the example of FIG. 3(d), the encoding unit 15 encodes the intermediate data corresponding to the data group by using the first entropy coder when the remark position is further towards the beginning of the data group than the switch position. The encoding unit 15 encodes the intermediate data corresponding to the data group by using the second entropy coder when the remark position is further towards the end of the data group than the switch position. In the case of FIG. 3(d), the intermediate data of “70”, “18”, “5” is encoded by the first entropy coder, and the intermediate data of “50”, “8”, “15”, “10” is encoded by the second entropy coder

For example, the encoding unit 15 can use static Huffman coding as the entropy coder. The static Huffman coding includes a step of calculating an appearance frequency of the intermediate data (first pass), and a step of encoding the intermediate data (second pass). The encoding unit 15 calculates a histogram corresponding to each of Huffman coding methods and designs Huffman codes at the first pass. The encoding unit 15 encodes a table of Huffman code lengths (or Huffman code trees) and the intermediate data by using the selected Huffman coding method, and generates the encoded data.

In this case, for example, the encoding unit 15 preferably includes a buffer holding the intermediate data and a histogram buffer corresponding to the number of static Huffman coding methods to be used by switching.

The output unit 16, for example, then outputs the obtained encoded data to a storage unit or a display unit on the client side (step S106). The processing of the data encoding apparatus 1 is finished at that point.

In this embodiment, the input data acquired by the acquisition unit 11 is noted as sample data of the image data. But the operation is not so limited. For example, the acquisition unit 11 can acquire a differential value between the sample value and a prediction value as the input data by using prediction of Differential Pulse-Code Modulation (DPCM). For example, the prediction method can be (1) a method of using a preceding sample value as a prediction value, or (2) a method of getting sum of products by using the preceding sample values and a weighting factor set in advance, and using the sum of products as the prediction value. However, the prediction method is not limited as noted above. As a further example, the acquisition unit 11 can acquire quantized values obtained by using DPCM as the input data.

Instead of acquiring the sample value or the differential value as the input data, the acquisition unit 11 can acquire a bit length needed for restoring values as the input data, encode the input data, and add the values expressed by the bit length to the encoded data. Therefore, the data encoding apparatus 1 can restrain deterioration of the encoding efficiency when the number of possible symbols of the input data is high.

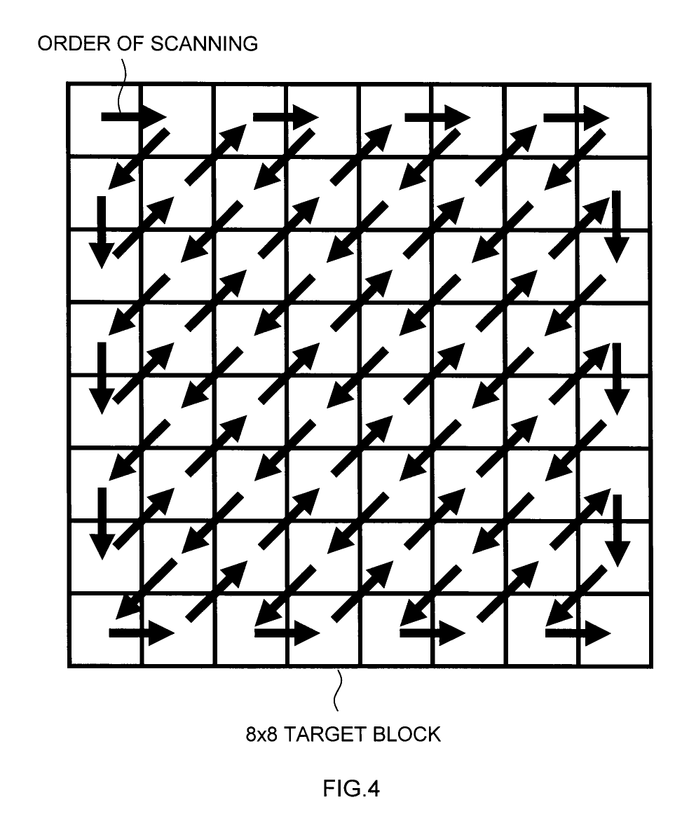

The acquisition unit 11 can acquire data arranged in order of lowness of frequency components of transformation coefficients obtained by applying a transformation (e.g. a block transformation) on each block of the image data. The block transformation may be 2-dimensional DCT (Discrete Cosine Transformation) when the image data is 2-dimensional data. When the image data is applied to the 2-dimensional block transformation, the acquisition unit 11 can acquire transformation coefficients arranged in the order set in advance as the input data. For example, the transformation coefficients may be arranged by zigzag scanning shown in FIG. 4. The block transformation may be Hadamard transformation, Discrete Sine Transformation (DST), or transformation using an orthonormal basis based on a principal component analysis of learning data or target data.

In this embodiment, the input data acquired by the acquisition unit 11 is an image data. However, the input data is not limited to image data. The input data may be any kind of data such as audio data, text data, or the like. When the input data is audio data, the block transformation can use MDCT, which is used in MPEG1-Audio.

In this embodiment, the conversion unit 12 converts the zero-run and the non-zero adjacent to the zero-run to the corresponding intermediate data by using the conversion table stored in advance for the input data. However, the embodiment is not so limited. For example, when the length of the zero-run exceeds a maximum length of the zero-run set in advance, the conversion unit 12 can generate the middle symbol expressing the zero-run having maximum length. When the probability of occurrence of zero in the input data is high, the data encoding apparatus 1 can encode the intermediate data generated by using the method above. Therefore, the encoding efficiency increases.

When it is a strong possibility that the same symbols are arranged in the input image, the conversion unit 12 can count the number of consecutive data of the same value (run length). When the run length is 1, the conversion unit 12 can assign the data of the amount of the input data to the intermediate data. When the run length is 2, the conversion unit 12 can assign the value that is the sum of the maximum value of the input data and the run length to a first intermediate data, and can assign the data of the amount of the input data to a second intermediate data.

The conversion unit 12 can hold a sliding dictionary data based on LZ77, and convert the data group into the intermediate data by using the sliding dictionary data. In this case, the size of the sliding dictionary, a shortest match length, and a longest match length are set in advance.

The conversion unit 12 can determine whether there is a match pattern in the sliding dictionary for the input data. When there is such a match pattern, the conversion unit 12 generates the intermediate data by adding “(the match length)−(the shortest match length)+1” to the maximum value on data in the data group. When there is no such match pattern, the conversion unit 12 uses the input data as the intermediate data.

Or, when there is a match pattern, the encoding unit 15 adds the position of the match pattern in the sliding dictionary data to the encoded data. The range of the intermediate data is “0”−“(the maximum value of the acquired data)+(the longest match length)+(the shortest match length)+1”. When the intermediate data does not exceed the maximum value on the acquired data, the conversion unit 12 regards it as the input data. When the intermediate data exceeds the maximum value on the acquired data, the conversion unit 12 regards “(the intermediate data)−(the maximum value of the acquired data)−1+(the shortest match length)” as the match length. Therefore, the original data can be restored.

The conversion unit 12 can register the input data used for conversion into the intermediate data on the sliding dictionary used for conversion to next intermediate data. The conversion unit 12 can prepare as many sliding dictionaries as entropy coders, and then switch the sliding dictionaries at the time of switching the entropy coders. In this case, the conversion unit 12 can ignore the switch position at determining the match length, and register the dictionary in accordance with the switch position at a time of registering the dictionary. At this time, the conversion unit 12 can divide the input unit at the switch position, and register each of data to a plurality of dictionaries.

(Modification 1)

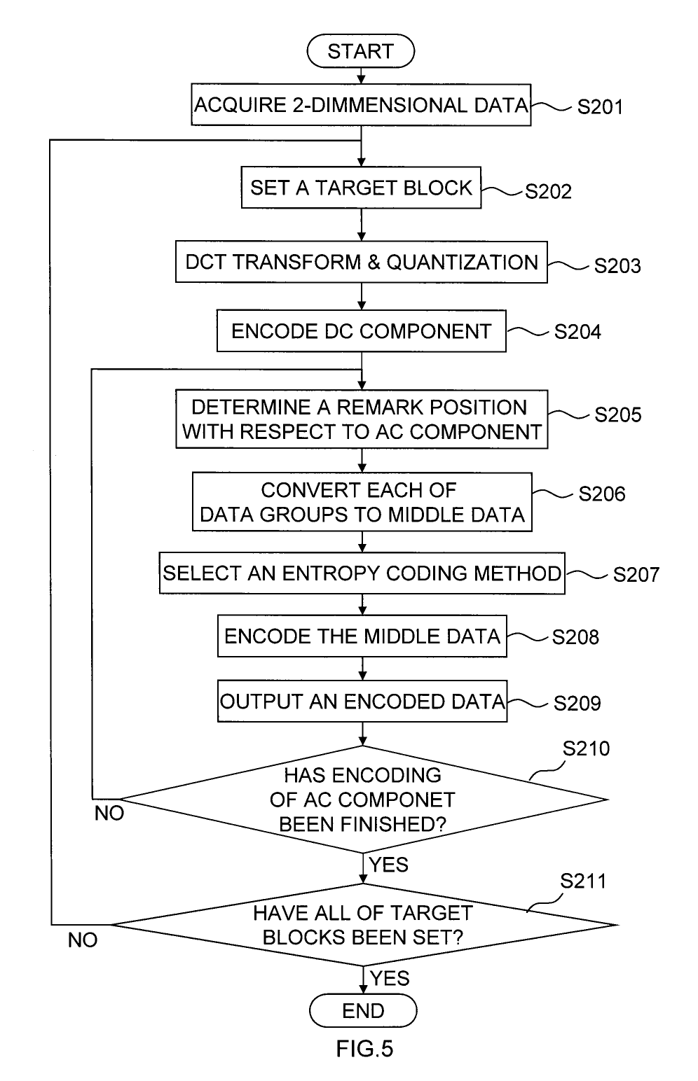

The data encoding apparatus 1 can apply a block transformation (e.g. DCT) to the input data, and perform the same processing as this embodiment. FIG. 5 shows a flow chart of processing of the data encoding apparatus 1 according to this modification.

The acquisition unit 11 acquires 2-dimensional data (step S201). The 2-dimensional data may be an image data or an internal 2-dimensional data of a medical diagnostic imaging equipment. The example of the internal 2-dimensional data includes B-mode data (Brightness mode data), color Doppler data, and k-space data used in a Magnetic Resonance Imaging (MRI).

The conversion unit 12 sets a block to be transformed (a target block) (step S202). The block size may be 4×4, 8×8, 16×8, 16×16, 32×16, 32×32. The block size may be a fixed size set in advance, or switched at each region.

The conversion unit 12 applies DCT transformation and quantization to the target block, and acquires a quantized DCT input data (step S203). For example, the conversion unit 12 can acquire a quantized DCT input data by the zigzag scanning shown in FIG. 4.

The encoding unit 15 encodes a DC component of the quantized DCT input data (step S204). For example, the encoding unit 15 can use an encoding method of DC components used in JPEG.

The determination unit 13 determines the remark position in the data group to be converted into the intermediate data about the input data of AC components of a quantized DCT coefficient (step S205). The remark position may be the beginning of the input data of AC components at a first time, and be the first AC component which has not been converted into the intermediate data from a second time.

The conversion unit 12 searches the data group including zero-run length and the non-zero adjacent to the zero-run by scanning the acquired input data of AC components, and converts each of the data group to the corresponding intermediate data (step S206).

The selection unit 14 selects an entropy coder for each of the intermediate data based on the determined remark position and a switch position information (step S207). The switch position information has been acquired and is held by the selection unit 14.

The encoding unit 15 encodes each of the intermediate data by using the selected entropy coder, to generate the encoded data (step S208). The output unit 16 outputs the obtained encoded data.

The determination unit 13 determines whether the encoding of the input data of AC components is finished or not in the target block (step S210). When the encoding is not finished (NO at S210), processing is returned to step S205.

When the encoding is finished (YES at S210), the conversion unit 12 determines whether conversion has been set for all of the target blocks or not. When conversion has not been set for all of the target blocks (NO at S211), the processing is returned to step S202. When conversion has been set for all of the target blocks (YES at 5211), the processing is completed.

The processing of the data encoding apparatus 1 according to this modification is explained above. In such processing, although the zero-run does not exceed the boundary of blocks, there is a case that it may exceed the switch position of entropy coders. When static Huffman coding is used, the switch position is preferably set between the beginning and the middle of the input data in the block. Therefore, the encoding efficiency increases. For example, when the block size is 8×8, the switch position is set in the data between 1st and 32nd, not set in the data between 33rd and 63rd. Therefore, the encoding efficiency increases. The selection unit 14 can hold such switch position information.

In the method using the flow in FIG. 5 all of the target blocks can have the same switch position, and the entropy coder used for each of the region of the data is set. Or there is another method in which the switch position is derived by using a numerical formula set in advance for the position of the target block in the 2-dimensional data, the entropy coder to be used in each region is selected in accordance with the number of exceeding the switch position.

(Modification 2)

When the input data is sample values of image data or audio data, or DPCM which is the prediction differential value thereof, for example, the switch position can be set at regular intervals in every number of data set in advance.

As a method of switching the entropy coder used for each of the data group in the set switching region, there is a method that calculates sample variance or unbiased variance, and uses a first entropy coder if the value is no more than a prescribed threshold, and uses a second entropy coder if the value is more than the prescribed threshold. A method of outputting the identification information (1 bit) of the used entropy coder just before encoding the beginning of the intermediate data exceeding the switch position can be implemented. The entropy coder is not limited to two types. The identification information may then be other than 1 bit.

That further modification of the embodiment is now explained.

When an input data is acquired, the background data encoding apparatus divides the input data, converts a plurality of data to an intermediate data in each region, and encodes the intermediate data. At the preceding process, the input data which would be converted into one intermediate data if it was not divided, is converted to two intermediate data because it is divided at the division boundary. If the intermediate data is encoded separately at the later part, the encoding efficiency decreases. This embodiment can restrain the decreasing of the encoding efficiency because of dividing of symbols, and encode the data efficiently.

### The Second Embodiment

A data decoding apparatus 2 according to a second embodiment decodes the encoded data encoded by the data encoding apparatus 1. The data decoding apparatus 2 decodes the encoded data to the intermediate data by applying an entropy decoding method, converts the intermediate data to the original data group by using the inverse conversion method corresponding to the conversion method used by the data encoding apparatus 1, and outputs the converted data group. The data decoding apparatus 2 selects an entropy decoding method based on the beginning position of the data group acquired by applying the inverse conversion to the intermediate data, when it decodes each of the intermediate data.

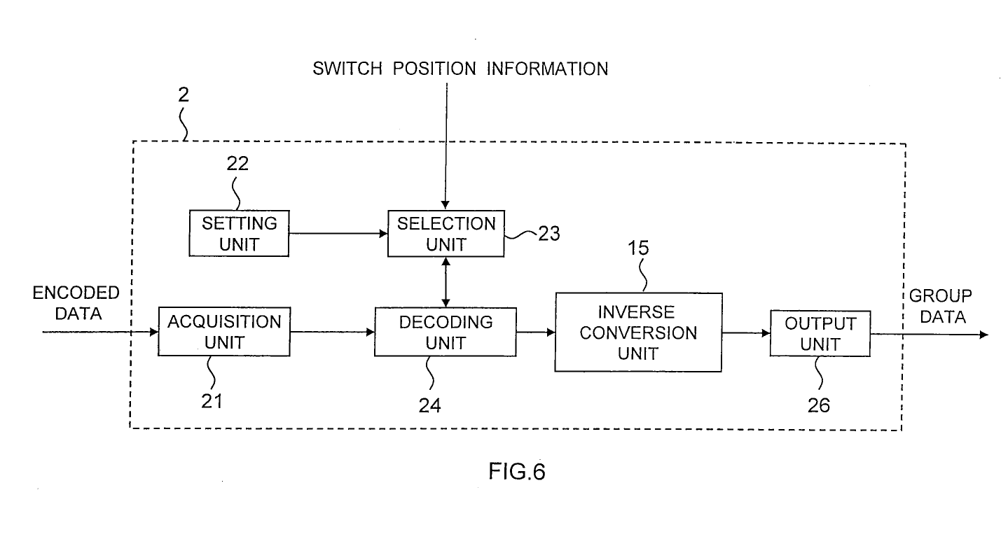

FIG. 6 is a bock diagram of a data decoding apparatus 2. The data decoding apparatus 2 includes an acquisition unit 21, a setting unit 22, a selection unit 23, a decoding unit 24, a conversion unit 25, and an output unit 26.

The acquisition unit 21 acquires the encoded data. For example the encoded data may be the data encoded by the data encoding apparatus 1 of FIG. 1.

The setting unit 22 sets the remark position of the beginning of the data, when the decoding unit 24 decodes the encoded data to each of the intermediate data.

The selection unit 23 holds the same switch position information as the data encoding apparatus 1 holds. The selection unit 23 selects an entropy decoding method for decoding each of the intermediate data in accordance with the remark position set by the setting unit 22.

The decoding unit 24 decodes the acquired encoded data to each of the intermediate data by using the selected entropy decoding method.

The conversion unit 25 converts the decoded intermediate data to the original data group by using the inverse conversion corresponding to the conversion used by the conversion unit 12 of the data encoding apparatus.

The output unit 16 outputs the data group.

The acquisition unit 21, the setting unit 22, the selection unit 23, the decoding unit 24, the conversion unit 25, and the output unit 26 may be realized by a CPU or processor and a memory used thereby.

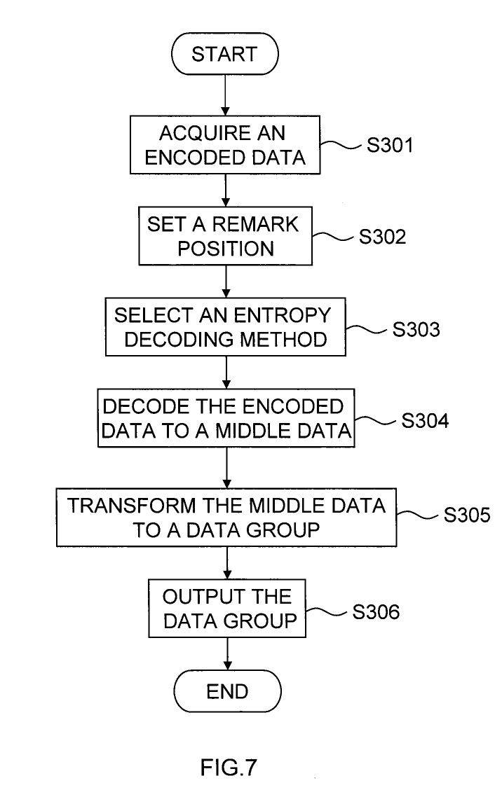

FIG. 7 is a flow chart of processing of the data decoding apparatus 2. The acquisition unit 21 acquires the encoded data (step S301). The setting unit 22 sets the remark position when the decoding unit 24 decodes the encoded data to each of the intermediate data (step S302). The selection unit 23 selects an entropy decoder for decoding each of the intermediate data in accordance with the remark position set by the setting unit 22 (step S303). The decoding unit 24 decodes the acquired encoded data to each of the intermediate data by using the selected entropy decoding method (step S304). The conversion unit 25 converts the decoded intermediate data to the original data group by using the inverse conversion corresponding to the conversion used by the conversion unit 12 of the data encoding apparatus (step S305). The output unit 16 outputs the data group. At that time the processing of the data decoding apparatus 2 is finished.

The data decoding apparatus 2 repeats the processing from the step of S302 to the step of S306 until all of encoded data is decoded.

As mentioned-above, in the first and second embodiments, the coding and decoding can be effectively executed.

In the disclosed embodiments, the processing can be performed by a computer program of computer executable instructions stored in a computer-readable medium.

In the embodiments, the computer readable medium may be, for example, a magnetic disk, a flexible disk, a hard disk, an optical disk (e.g., CD-ROM, CD-R, DVD), an optical magnetic disk (e.g., MD). However, any computer readable medium, which is configured to store a computer program for causing a computer to perform the processing described above, may be used.

Furthermore, based on an indication of the program installed from the memory device to the computer, an OS (operation system) operating on the computer, or MW (middle ware software), such as database management software or network, may execute one part of each processing to realize the embodiments.

Furthermore, the memory device is not limited to a device independent from the computer. By downloading a program transmitted through a LAN or the Internet, a memory device in which the program is stored is included. Furthermore, the memory device is not limited to one. In the case that the processing of the embodiments is executed by a plurality of memory devices, a plurality of memory devices may be included in the memory device.

A computer or processor may execute each processing stage of the embodiments according to the program stored in the memory device. The computer may be one apparatus such as a personal computer or a system in which a plurality of processing apparatuses are connected through a network. Furthermore, the computer is not limited to a personal computer. Those skilled in the art will appreciate that a computer includes a processing unit in an information processor, a microcomputer, and so on. In short, the equipment and the apparatus that can execute the functions in embodiments using the program are generally called the computer.

While certain embodiments have been described, these embodiments have been presented by way of examples only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An apparatus for encoding data, comprising:
an acquisition unit configured to acquire an input data including a plurality of arranged data;
a conversion unit configured to search a data group including a first consecutive data and a second data adjacent to the first consecutive data, each data of the first consecutive data having a first value and the second data having a second value, and to convert the data group into an intermediate data;
a selection unit configured to select a selected encoding method among a plurality of encoding methods, at a time of encoding the intermediate data based on where a beginning of the data group corresponding to the intermediate data exists in the input data; and
an encoding unit configured to encode the intermediate data by using the selected encoding method.

2. The apparatus according to claim 1, wherein the first consecutive data is data of consecutive zeroes and the second data is a non-zero data.

3. The apparatus according to claim 1,
wherein the selection unit selects the selected encoding method based on a switch position information for selecting different encoding methods in front and behind of a prescribed remark position in the input data.

4. The apparatus according to claim 3,
wherein the conversion unit converts the data group to the intermediate data by using a conversion table assigning an identification number to each combination of the first consecutive data and the second data.

5. The apparatus according to claim 4,
wherein the acquisition unit acquires conversion coefficients of an image data orthogonally converted.

6. The apparatus according to claim 1,
wherein the encoding unit encodes the intermediate data by using Huffman coding.

7. An apparatus for decoding data, comprising:
an acquisition unit configured to acquire an encoded data;
a setting unit configured to set a remark position representing a position of data to be decoded;
a selection unit configured to select a selected decoding method among a plurality of decoding methods, based on where a beginning of the data at the remark position exists in the encoded data;
a decoding unit configured to decode the encoded data to an intermediate data by using the selected decoding method;
a conversion unit configured to convert the intermediate data including a first consecutive data and a second data adjacent to the first consecutive data, each data of the first consecutive data having a first value and the second data having a second value.

8. The apparatus according to claim 7, wherein the first consecutive data is data of consecutive zeroes and the second data is a non-zero data.

9. A method for encoding data, comprising:
acquiring an input data including a plurality of arranged data;
searching a data group including a first consecutive data and a second data adjacent to the first consecutive data, each data of the first consecutive data having a first value and the second data having a second value, and converting the data group into an intermediate data;
selecting a selected encoding method among a plurality of encoding methods, at a time of encoding the intermediate data based on where a beginning of the data group corresponding to the intermediate data exists in the input data; and
encoding the intermediate data by using the selected encoding method.

10. The method according to claim 9, wherein the first consecutive data is data of consecutive zeroes and the second data is a non-zero data.

11. A data decoding method, comprising:
acquiring an encoded data;
setting a remark position representing a position of data to be decoded;
selecting a selected decoding method among a plurality of decoding methods, based on where a beginning of the data at the remark position exists in the encoded data;
decoding the encoded data to an intermediate data by using the selected decoding method;
converting the intermediate data including a first consecutive data and a second data adjacent to the first consecutive data, each data of the first consecutive data having a first value and the second data having a second value.

12. The method according to claim 11, wherein the first consecutive data is data of consecutive zeroes and the second data is a non-zero data.
